(19) United States
(12) Patent Application Publication
(10) Pub. No.: US 2008/0297258 A1
(43) Pub. Date: Dec. 4, 2008

(54) Variable impedance circuit; and variable impedance system, filter circuit, amplifier, and communication system using the same

(76) Inventors: Tomohiro Naito, Anpachi-gun (JP); Toru Dan, Gifu-shi (JP)

Correspondence Address: MCDERMOTT WILL & EMERY LLP, 600 13TH STREET, N.W., WASHINGTON, DC, 20005-3096, US

(21) Appl. No.: 12/153,791

(22) Filed: May 23, 2008

(30) Foreign Application Priority Data
May 23, 2007 (JP) 2007-137233

(51) Int. Cl. H03H 11/10; H03G 5/10

(52) U.S. Cl. 330/282; 327/581; 327/552

(57) ABSTRACT

A first transistor includes: a first terminal that receives one of differential input signals; a second terminal that receives a control signal for varying an impedance; a third terminal connected to the second transistor; and a fourth terminal that supplies a potential to a substrate. A second transistor includes: a fifth terminal that receives the other of the differential input signals; a sixth terminal that receives a control signal, the seventh terminal connected to the first transistor, and the eighth terminal that supplies a potential to a substrate. The third terminal, the fourth terminal, the seventh terminal, and the eighth terminal are connected together.

### CROSS-REFERENCE TO RELATED APPLICATIONS

This application is based upon and claims the benefit of priority from the prior Japanese Patent Application No. 2007-137233, filed on May 23, 2007, the entire contents of which are incorporated herein by reference.

### BACKGROUND OF THE INVENTION

1. Field of the Invention

The present invention relates to a variable impedance circuit using an internal resistance of a transistor; and a variable impedance system, a filter circuit, an amplifier, and a communication system using the same.

2. Description of the Related Art

A variable impedance circuit is used for varying an amount of signals passing through a switch, an amount of signals attenuating in an attenuator, and a gain in a variable gain amplifier, or the like. FIG. 1 illustrates an example of a variable impedance circuit according to a conventional technology. As shown in FIG. 1, the gate terminal of the FET 4a is connected to one end of the resistive element 6a and to one and of the resistive element 7, the drain of the same to the I/O terminal 2 and to one end of the capacitor 8a, and the source of the same to the source terminal of an FET, respectively. The gate terminal of the FET 4b is connected to the other end of the resistive elements 7 and to one end of the resistive element 5b, the drain of the same to the I/O terminal 3 and to one end of the capacitor 8b, respectively. The other end of the capacitor 8a is connected to the other end of the resistive element 6a and to one end of the resistive element 5a, and the other end of the capacitor 8b is connected to the other end of the resistive element 6b and to one end of the resistive element 5b. The other end of the resistive element 5a and the other end of resistive element 5b are connected to the impedance control terminal 1. By connecting the two FETs 4a and 4b in series, one of the two is made to function like a diode, thereby suppressing a great deterioration in the linearity of current-voltage, which is caused by the polarity of an input signal voltage or the like.

### SUMMARY OF THE INVENTION

The present inventors have found out a variable impedance circuit having a better linearity over a broad frequency band than the variable impedance circuit shown in FIG. 1.

A variable impedance circuit of an embodiment of the present invention is a variable impedance circuit in which a first transistor and a second transistor are connected in series. The first transistor includes a first terminal that receives one of differential input signals, and a second terminal that receives a control signal for varying an impedance, a third terminal connected to the second transistor, and a fourth terminal that supplies a potential to a substrate (a semiconductor substrate), and the second transistor includes a fifth terminal that receives the other of the differential input signals, a sixth terminal that receives the control signal, a seventh terminal connected to the first transistor, and an eighth terminal that supplies a potential to the substrate (the semiconductor substrate). The third terminal, the fourth terminal, the seventh terminal, and the eighth terminal are connected together. Specifically, when a NMOSFET is adopted, the NMOSFET has a well structure in which a semiconductor region having a polarity electrically opposite to the substrate, in other words, an n-type semiconductor region, is formed in the p-type semiconductor substrate; and the back gate terminal thereof is connected to the well; and the well may or may not be common between the above first transistor and second transistor. On the other hand, when a PMOSFET is adopted, the back gate terminal thereof is directly connected to the substrate.

### BRIEF DESCRIPTION OF THE DRAWINGS

FIG. 1 is a diagram illustrating the structure of a variable impedance circuit according to a conventional technology;

FIG. 2 is a diagram illustrating the structure of a variable impedance circuit according to an embodiment of the present invention;

FIG. 3A is a graph representing current value flowing when differential voltages are applied to I/O terminals in a low frequency region;

FIG. 3B is a graph representing current value flowing when differential voltages are applied to I/O terminals in a high frequency region;

FIG. 4 is a diagram illustrating the structure of a variable impedance circuit according to the modification example 1 of the embodiment;

FIG. 5 is a diagram illustrating the structure of a variable impedance circuit according to the modification example 2 of the embodiment;

FIG. 6 is a diagram illustrating the structure of a variable impedance system having a plurality of variable impedance circuits controlled by a single control signal CTRL;

FIG. 7 is a diagram illustrating the structure of a sixth-order low-pass filter circuit to which a variable impedance circuit according to the present embodiment is applied;

FIG. 8 is a diagram illustrating the structure of a differential amplifier circuit to which a variable impedance circuit according to the present embodiment is applied;

FIG. 9 is a diagram illustrating the structure of a high-pass filter to which a variable impedance circuit according to the present embodiment is applied;

FIG. 10 is a diagram illustrating the structure of an amplifier to which a variable impedance circuit according to the present embodiment is applied;

FIG. 11 is a diagram illustrating a communication system in which a variable impedance circuit according to the embodiment is used.

### DETAILED DESCRIPTION OF THE INVENTION

The invention will now be described by reference to the preferred embodiments. This does not intend to limit the scope of the present invention, but to exemplify the invention.

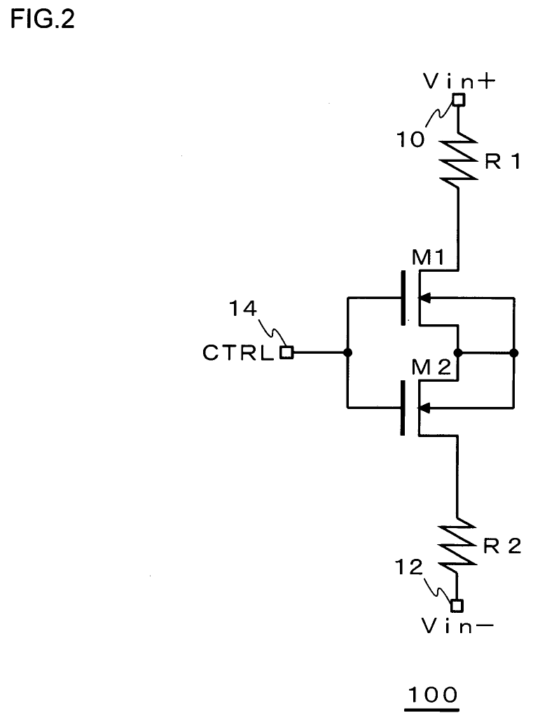

FIG. 2 illustrates the structure of a variable impedance circuit 100 according to an embodiment of the present invention. The variable impedance circuit 100 is a differential type variable impedance circuit, and includes a first transistor M1, a second transistor M2, a first resistance R1, a second resistance R2, a first I/O terminal 10, a second I/O terminal 12, and a control terminal 14. Differential signals, such as sine waves, are inputted to the first I/O terminal 10 and the second I/O terminal 12. It is preferable that the gate sizes of the first transistor M1 and the second transistor M2, and the resistance values of the first resistance R1 and the second resistance R2, are close together, respectively. When the gate sizes and the resistance values are respectively equal, maximum effects are achieved.

The first transistor M1 and the second transistor M2 are constituted by the N channel type MOSFETs (Metal-Oxide-Semiconductor Field Effect Transistors), respectively. The first transistor M1 and the second transistor M2 are respectively provided with four terminals, which are the source terminal, the gate terminal, the drain terminal, and the back gate terminal.

The first terminal of the first transistor M1 is connected to the first I/O terminal 10 via the first resistance R1. The second terminal of the first transistor M1 is the gate terminal connected to the control terminal 14. The control signal CTRL for varying an impedance of the variable impedance circuit 100 is inputted to the control terminal 14. The second terminal of the first transistor M1 is connected to the seventh terminal of the second transistor M2 mentioned later. Either of the second terminal and the third terminal, which has a higher potential, serves as a drain terminal, while the other as a source terminal. The fourth terminal of the first transistor M1 is the back gate terminal (also referred to as the substrate terminal), which is a terminal for supplying a voltage to the substrate, not to the gate side of a channel to be formed.

The fifth terminal of the second transistor M2 is connected to the second I/O terminal 12 via the second resistance R2. The sixth terminal of the second transistor M2 is the gate terminal connected to the control terminal 14. The seventh terminal of the second transistor M2 is connected to the second terminal of the first transistor M1. Either of the sixth terminal and the seventh terminal, which has a higher potential, serves as a drain terminal, while the other as a source terminal. The eighth terminal of the second transistor M2 is the back gate terminal.

All of the third terminal, the fourth terminal, the seventh terminal, and the eighth terminal are short-circuited to have the same potential. When integrating the first transistor M1 and the second transistor M2, a triple well structure is used in order to separate the substrates terminals of the first transistor M1 and the second transistor M2 from the substrate terminal of a peripheral circuit.

As shown in the following equation (1), a drain-source current Ids flows through the first transistor M1 and the second transistor M2 in accordance with a gate-source voltage V_{gs} and a drain-source voltage V_{ds}, in the non-saturation region, i.e., in the linear region:

I_{ds}=2K{(V_{gs}−V_{T})−V_{ds}/2}V_{ds} (1)

wherein K represents a transconductance parameter; and V_{T} represents a threshold voltage.

The threshold voltage VT is represented by the following equation (2):

V_{T}=V_{T0}+γ{√(2φ_{gs}+V_{sb})−√(2φ_{gs})} (2)

wherein γ represents a device constant; φ represents a surface potential in a strong inversion layer; and V_{sb} represents a source-substrate voltage.

When a high drain-source voltage is applied to the first transistor M1 or the second transistor M2, either of the two falls into the diode operation region, thereby the characteristic as a variable impedance circuit is not obtained. Herein, the diode operation region refers to a region where a drain-source voltage becomes higher in a negative direction to exceed a negative threshold. When exceeding the negative threshold, a drain-source current starts flowing like in a diode.

To prevent this from happening, the first resistance R1 and the second resistance R2 are inserted between the first I/O terminal 10 and the first transistor M1, and between the second I/O terminal 12 and the second transistor M2, respectively. The first resistance R1 and the second resistance R2 divide the voltages applied to the first I/O terminal 10 and the second I/O terminal 12 to reduce the drain-source voltage to be applied to the first transistor M1 and the second transistor M2. At the time, the first transistor M1 and the second transistor M2 operate in a deep linear region.

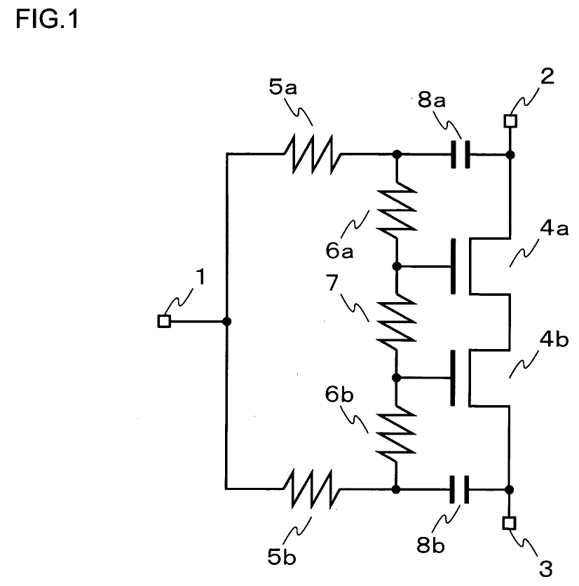

Herein, the characteristic of the variable impedance circuit 100 according to the embodiment illustrated in FIG. 2 will be compared to that of the variable impedance circuit according to a conventional technology illustrated in FIG. 1. In order to make the conditions even, it is assumed that the first resistance R1 and the second resistance R2 are connected to the both I/O terminals of the variable impedance circuit according to a conventional technology, in the same way as with FIG. 2.

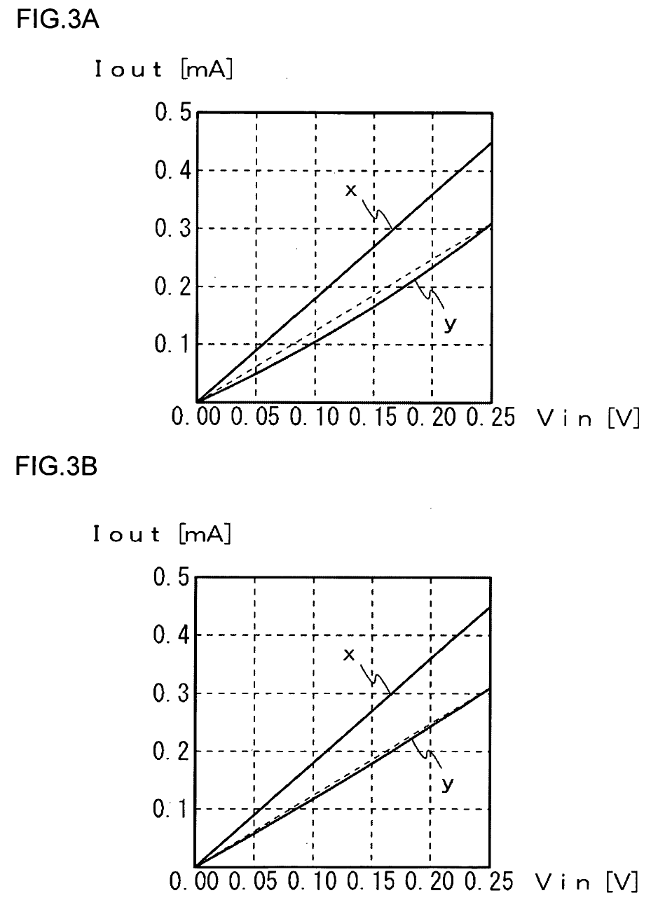

FIG. 3A is a graph representing current value flowing when differential voltages are applied to the I/O terminals in a low frequency region. FIG. 3B is a graph representing current value flowing when differential voltages are applied to the I/O terminals in a high frequency region. In the graphs, x represents the characteristic of the variable impedance circuit 100 according to the embodiment illustrated in FIG. 2, while y represents that of the variable impedance circuit according to a conventional technology illustrated in FIG. 1.

The circuit according to a conventional technology has still a large distortion in a low frequency region, while having an improved one in a high frequency region. This indicates that a circuit structure according to a conventional technology has an advantage only in a high frequency region. This is because a circuit according to a conventional technology has a frequency dependence due to a time constant specified by a resistance and a capacitance, making the circuit not suitable for the use in a low frequency region. By contrast, it can be understood that the circuit according to the embodiment has a smaller distortion than the circuit according to a conventional technology and has better linearity ranging from a low frequency region to a high frequency region.

As mentioned above, better linearity can be obtained over a wide band according to the embodiment. Since the source terminal and the substrate terminal of a transistor are always short-circuited, deterioration of the linearity caused by the substrate effect can be suppressed. That is, a source-substrate voltage V_{sb} in the above equation (2) can always be zero. When the sauce terminal and the substrate terminal are not short-circuited, resistance values of the first transistor M1 and the second transistor M2 greatly vary each other when differential signals are inputted, therefore the source-substrate voltage V_{sb} also varies. Thereby, a distortion occurs in the threshold voltage VT of the first transistor M1 or the second transistor M2, causing a distortion in the drain-source current Ids. The structure according to the present embodiment can prevent this from happening. In addition, since the structure of the embodiment does not use an element, such as a capacitance, a better characteristic can be obtained over a wide band ranging from a direct current to a high frequency region.

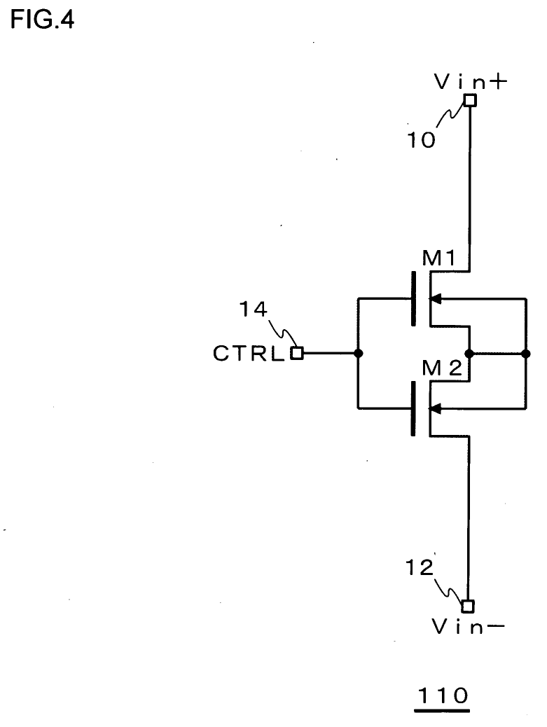

FIG. 4 illustrates the structure of a variable impedance circuit 110 according to the modification example 1 of the embodiment. The variable impedance circuit 110 according to the modification example 1 has a structure in which the first resistance R1 and the second resistance R2 are removed from the variable impedance circuit 100 illustrated in FIG. 2. When the ranges of the differential voltages, which are applied to the first I/O terminal 10 and the second I/O terminal 12, are ensured in advance not to fall in the diode operation region, the circuit can be simplified by removing the first resistance R1 and the second resistance R2.

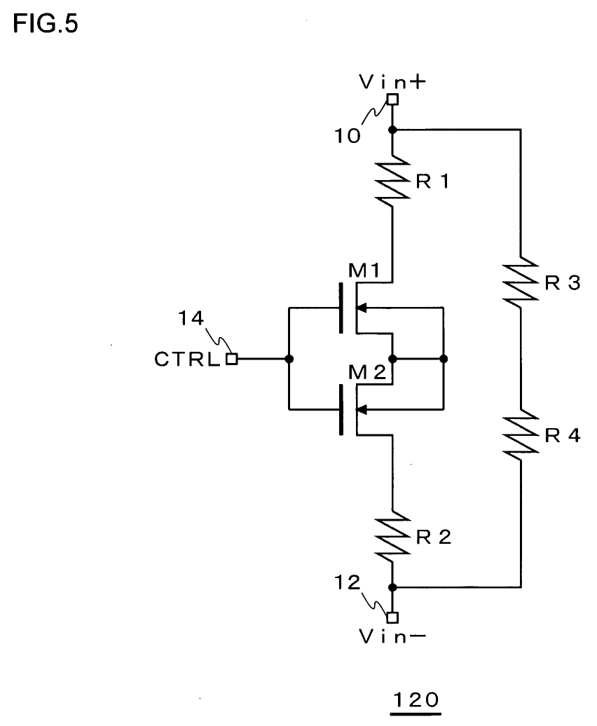

FIG. 5 illustrates the structure of a variable impedance circuit 120 according to the modification example 2 of the embodiment. The variable impedance circuit 120 according to the modification example 2 has a structure in which a third resistance R3 and a fourth resistance R4 are added to the variable impedance circuit 100 illustrated in FIG. 2. The third resistance R3 and the fourth resistance R4 are connected in series, and the series circuit is connected in parallel to a series circuit including the first resistance R1, the first transistor M1, the second transistor M2, and the second resistance R2. The series circuit including the third resistance R3 and the fourth resistance R4 may be connected in parallel to the series circuit including the first transistor M1 and the second transistor M2 of the variable impedance circuit 110 according to the modification example 1. A resistance connected in parallel to the variable impedance circuit 100 illustrated in FIG. 2, may be a variable impedance circuit having the same structure as that of the variable impedance circuit 100 illustrated in FIG. 2.

According to the modification example 2, the contribution rate of the resistance values in the first transistor M1 and the second transistor M2 to the total impedance value, is reduced in comparison with the variable impedance circuit 100 illustrated in FIG. 2, therefore the influence by a distortion occurring in the first transistor M1 and the second transistor M2 can be further reduced. Accordingly, the linearity can be more improved while the variable range of the impedance is narrowed, in comparison with the variable impedance circuit 100 illustrated in FIG. 2.

An application example of the variable impedance circuit 100 according to the present embodiment will be described below. An example will be at first explained in which the circuit 100 is applied to an active filter circuit. As a premise for that, an example will be explained in which a plurality of the variable impedance circuits 100 according to the embodiment are provided, and each impedance of each variable impedance circuit 100a, 100b, and 100c is controlled by a single control signal CTRL.

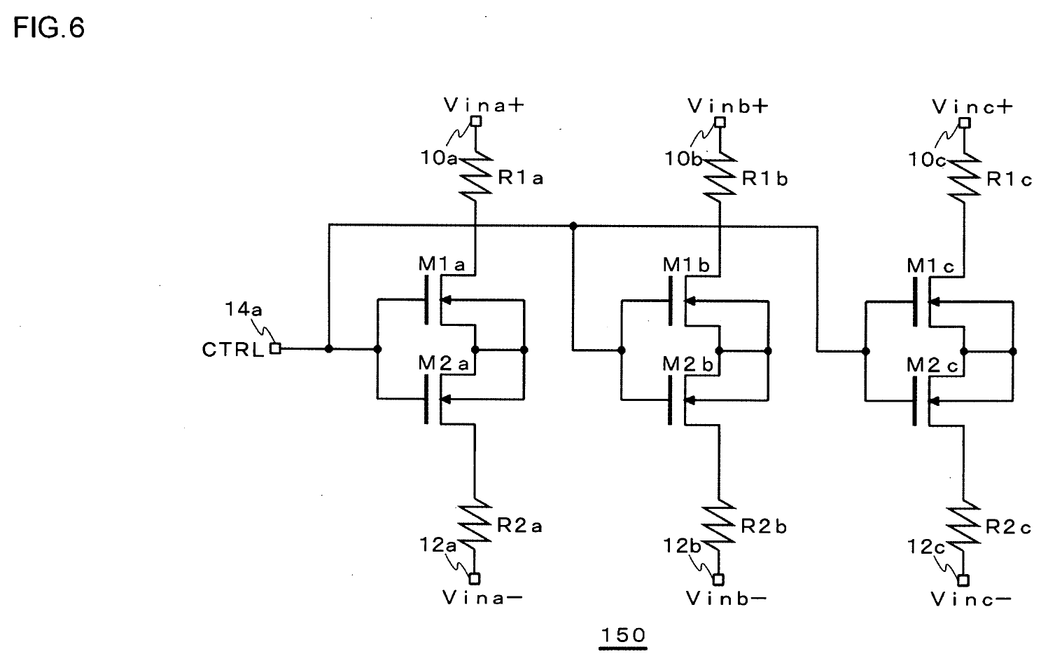

FIG. 6 is a diagram illustrating the structure of a variable impedance system 150 having a plurality of variable impedance circuits controlled by a single control signal CTRL. In the structure of FIG. 6, when the resistance values and the gate sizes of the transistors are set so as to satisfy the conditions of the following equations (3), (4), (5), and (6), each impedance of the plurality of the variable impedance circuits can be controlled at a same time while the ratio of the impedances being maintained, with the use of only a single control terminal as shown in the equation (7):

R1a: R1b: R1c=α1: α2: α3 (3)

R2a: R2b: R2c=α1: α2: α3 (4)

(L1a/W1a): (L1b/W1b): (L1b/W1b)=α1: α2: α3 (5)

(L2a/W2a): (L2b/W2b): (L2b/W2b)=α1: α2: α3 (6)

wherein L1 represents the gate length of the first transistor M1; W1 represents the gate width of the first transistor M1; L2 represents the gate length of the second transistor M2; and W2 represents the gate width of the second transistor M2:

Z1: Z2: Z3=α1: α2: α3 (7)

wherein Z represents the value of the impedance of the variable impedance circuit 100.

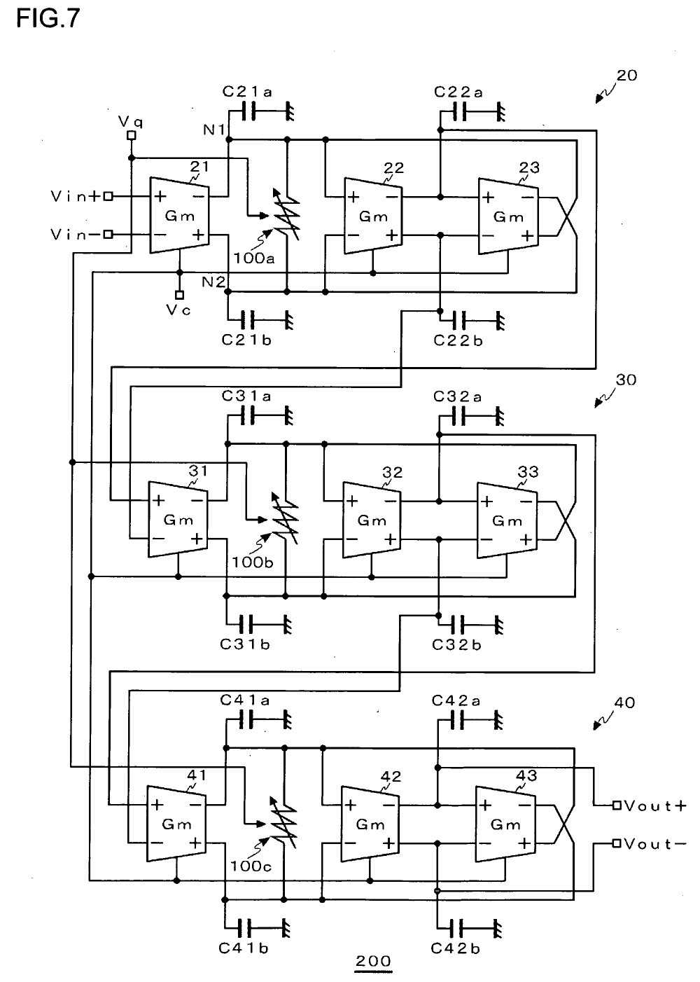

FIG. 7 is a diagram illustrating the structure of a sixth-order low-pass filter circuit 200 to which the variable impedance circuit 100 according to the embodiment is applied. The sixth-order low-pass filter circuit 200 has a structure in which the second-order low-pass filter circuits 20, 30, and 40 are connected in three-stage cascade. The numbers of orders and stages of the low-pass filter circuit can be designed arbitrarily. In FIG. 7, the Q factor or the pole of the low-pass filter circuit is controlled by applying the structure illustrated in FIG. 6. The Q factor is an index indicating the magnitude of energy which can be accumulated in or released from the filter.

The second-order low-pass filter 20 in the first stage includes three fully-differential type OTAs (Operational transconductance amplifiers) 21, 22, and 23, and 2 sets of respective pairs of capacitances: C21a and C21b; and C22a and C22b. To the non-inversion input terminal and the inversion input terminal of the first OTA 21, the differential input voltages Vin± are inputted. The inversion output terminal of the first OTA 21 is connected to one end of the first capacitance C21a, to the non-inversion input terminal of the second OTA 22, and to the non-inversion output terminal of the third OTA 23. The non-inversion output terminal of the first OTA 21 is connected to one end of the second capacitance C21b, to the non-inversion input terminal of the second OTA 22, and to the non-inversion output terminal of the third OTA 23. The other ends of the first capacitance C21a and the second capacitance C21b are connected to a predetermined fixed potential, herein, the ground potential. It is noted that the nodes of the first capacitance C21a and the second capacitance C21b, which are opposite to the ground, are denoted by the first node N1 and the second node N2, respectively.

The inversion input terminal of the second OTA 22 is connected to the first node N1, and the non-inversion input terminal of the second OTA 22 to the second node N2. The non-inversion output terminal of the second OTA 22 is connected to one end of the third capacitance C22a, to the non-inversion input terminal of the third OTA 23, and to the non-inversion input terminal of the second-order low-pass filter circuit in the next stage. The inversion output terminal of the second OTA 22 is connected to one end of the fourth capacitance C22b, to the inversion input terminal of the third OTA 23, and to the inversion input terminal of the second-order low-pass filter circuits in the next stage. The non-inversion input terminal of the third OTA 23 is connected to the first node N1, and the inversion input terminal of the second OTA 22 to the second node N2.

The first OTA 21 converts the differential input voltages Vin± to currents in accordance with the transconductance Gm. The first capacitance C21a and the second capacitance C21b integrate the outputs of the first OTA 21. The second OTA 22 converts the voltages of the first node N1 and the second node N2 to currents in accordance with the transconductance Gm. The third capacitance C22a and the fourth capacitance C22b integrate the outputs of the second OTA 22. The outputs of the third OTA 23 are feedbacked to the outputs of the first OTA 21 and the inputs of the second OTA 22. With this structure, a second-order transfer function can be realized. In addition to this structure, the first variable impedance circuit 100a is connected between the first node N1 and the second node N2.

The second-order low-pass filter circuit 30 in the second stage includes three fully-differential type OTAs 31, 32, and 33, and 2 sets of respective pairs of capacitances: C31a and C31b; and C32a and C32b. The second-order low-pass filter circuit 40 in the third stage includes three fully-differential type OTAs 41, 42, and 43, and two sets of respective pairs of capacitances: C41a and C41b; and C42a and C42b. The structures of the second-order low-pass filter circuits 30 and 40 in the second stage and the third stage are the same as that of the second-order low-pass filter circuit 20 in the first stage, therefore description with respect thereto will be omitted.

The transconductance values Gm of the first OTA 21, the second OTA 22, the third OTA 23, the fourth OTA 31, the fifth OTA 32, the sixth OTA 33, the seventh OTA 41, the eighth OTA 42, and ninth OTA 43, are controlled by the same control signal Vc. The impedance values of the first variable impedance circuit 100a, the second variable impedance circuit 100b, and the third variable impedance circuit 100c, are controlled by the same control signal Vq.

The Q factor of each stage of the sixth-order low-pass filter circuit 200 is represented by the following equations (8), (9), and (10) from the first stage:

Q1(Vc)=Gm•Z1•√(C21/C22) (8)

Q2(Vc)=Gm•Z2•√(C31/C32) (9)

Q3(Vc)=Gm•Z3•√(C41/C42) (10).

In the sixth-order low-pass filter circuit 200, when the transconductance value Gm varies by a variation of an element among transistors, the Q factor of each stage of the circuit 200 varies accordingly. In order to correct this, it is necessary to return the Q factor of each stage to a desired preset value by controlling the first variable impedance circuits 100a-100c and adjusting the each impedance value. When each impedance of the variable impedance circuits 100a-100c is controlled by a single control terminal, it becomes impossible to return all of the Q factor of each stage to desired preset values simultaneously, if the ratio of each impedance varies depending on a control voltage. In this case, it is necessary to control each of a plurality of variable impedances independently, making the control difficult or complicated.

By contrast, when using the structure illustrated in FIG. 6, a plurality of variable impedances can be controlled simultaneously by a single control signal while maintaining the ratio of the impedances constant, allowing a filter correction mechanism by a single control system to be realized. In addition, linearity can be improved over a wide band by applying the variable impedance circuit 100 according to the embodiment.

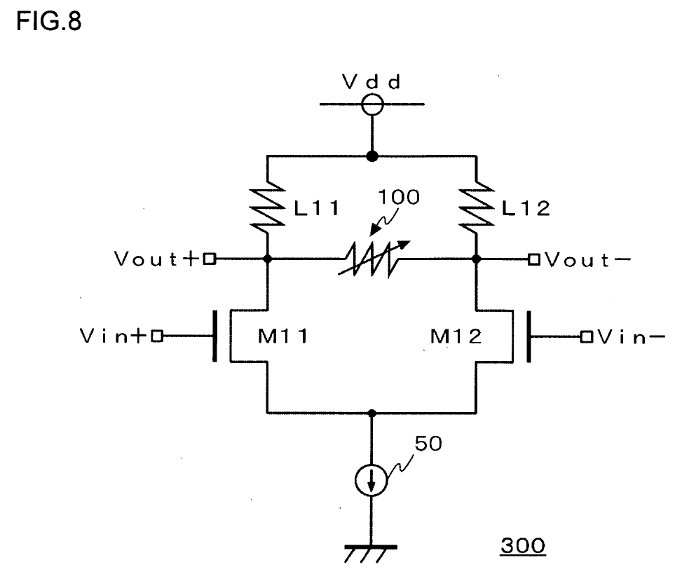

An example where the variable impedance circuit 100 according to the embodiment is applied to a differential amplifier circuit will be described below. A differential amplifier circuit is widely used for amplification in a high frequency band. FIG. 8 is a diagram illustrating the structure of a differential amplifier circuit 300 to which the variable impedance circuit 100 according to the embodiment is applied. The differential amplifier circuit 300 includes a pair of transistors M11 and M12, a constant current source 50, a pair of loads L11 and L12, and the variable impedance circuit 100. As for the loads L11 and L12, a resistance, a transistor with its gate potential fixed, or a resonator, or the like, can be used.

Differential input signals Vin± are inputted to the gate terminals of the pair of transistors M11 and M12. The source terminals of the pair of transistors M11 and M12 are commonly connected to the constant current source 50. The other end of the constant current source 50 is connected to a fixed potential, herein the ground potential. The drain terminals of the pair of transistors M11 and M12 are connected to the pair of loads L11 and L12, respectively. The other end of the pair of loads L11 and L12 are connected to a predetermined fixed potential, herein the power supply potential Vdd. The variable impedance circuit 100 according to the present embodiment is connected between the drain terminals of the pair of transistors M11 and of M12. Alternatively, the variable impedance circuits 110 and 120 according to the modification examples 1 and 2 may be connected.

The pair of transistors M11 and M12 generate differential output signals Vout± by applying the drain-source current corresponding to the differential input signals Vin± to the pair of loads L11 and L12, respectively. According to the present application example, the linearity of an amplifier operating at low gain can be improved better than the case where a conventional variable impedance circuit is used.

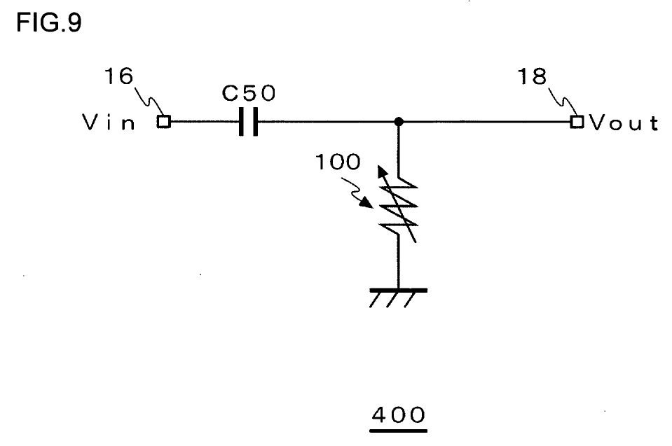

An example where the variable impedance circuit 100 according to the present embodiment is applied to a passive filter will be described below. FIG. 9 is a diagram illustrating the structure of a high-pass filter 400 to which the variable impedance circuit 100 according to the present embodiment is applied. The high-pass filter 400 includes a capacitance C50 and the variable impedance circuit 100. The capacitance C50 is provided between an input terminal 16 and an output terminal 18. The variable impedance circuit 100 is connected to the side of the output terminal 18 of the capacitance C50. Alternatively, the variable impedance circuits 110 and 120 according to the modification examples 1 and 2 may be connected. The other end of the variable impedance circuit 100 is connected to a predetermined fixed potential, herein the ground potential. A cut-off frequency can be controlled by controlling the impedance value of the variable impedance circuit 100. The linearity can be improved better than the case where a conventional variable impedance is used, over a wide band by applying the variable impedance circuit 100 according to the embodiment.

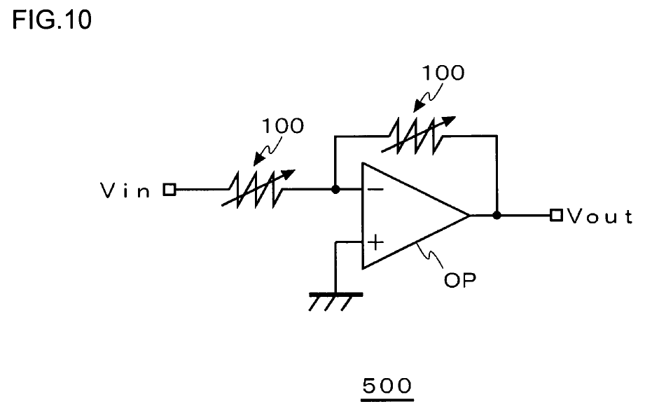

An example where the variable impedance circuit 100 according to the present embodiment is applied to an amplifier using an op-amp will be described below. An amplifier using an op-amp is widely used for amplification in a low frequency band. FIG. 10 is a diagram illustrating the structure of an amplifier 500 to which the variable impedance circuit 100 according to the present embodiment is applied. The amplifier 500 includes an op-amp OP and the two variable impedance circuits 100. One of the variable impedance circuits 100 is connected to the inversion input terminal of the op-amp OP, while a predetermined fixed potential, herein the ground potential, is connected to the non-inversion input terminal of the op-amp. The other variable impedance circuit 100 is inserted on the feedback path between the output terminal and the inversion input terminal of the op-amp. Alternatively, the variable impedance circuits 110 and 120 according to the modification examples 1 and 2 may be connected, instead of at least one of the variable impedance circuits 100.

The amplifier 500 inverts and amplifies an input voltage in accordance with the impedance ratio of the two variable impedance circuits 100. A voltage gain can be controlled by controlling the impedance value of at least one of the variable impedance circuits 100. The linearity can be improved better than the case where a conventional variable impedance is used, over a wide band by applying the variable impedance circuit 100 according to the embodiment.

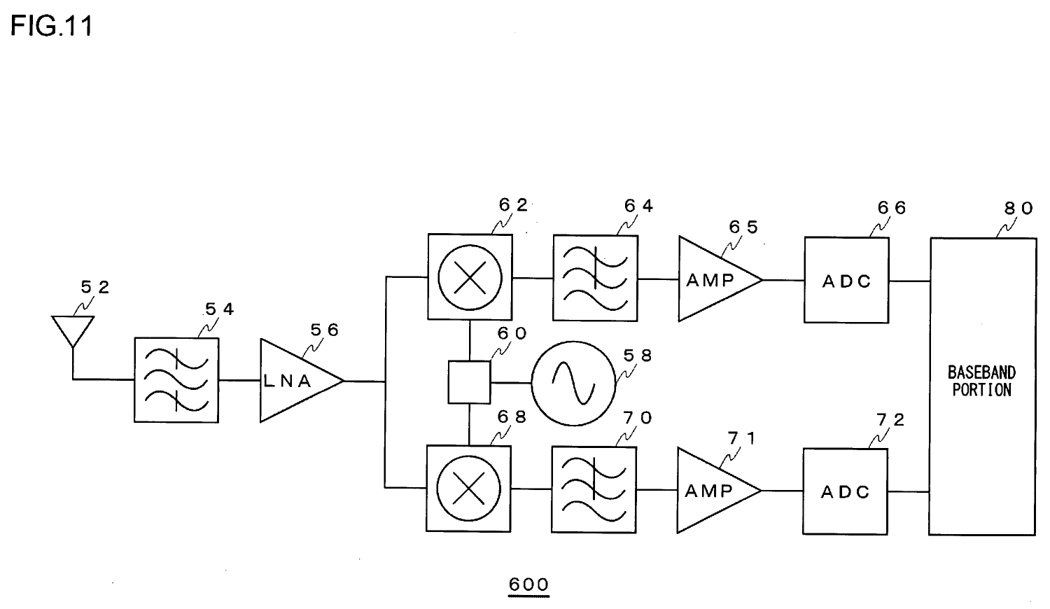

FIG. 11 is a diagram illustrating a communication system 600 in which the variable impedance circuit 100 according to the embodiment is used. Although the communication system 600 in FIG. 11 shows a direct conversion receiver (DCR), the system 600 is not limited thereto and is also applicable to other type receivers, such as a heterodyne receiver.

The communication system 600 includes an antenna 52, a band-pass filter 54, an LNA (Low Noise Amplifier) 56, a local oscillator 58, a phase shifter 60, mixers 62 and 68, low-pass filter circuits 64 and 70, variable gain amplifiers 65 and 71, and AD conversion circuits 66 and 72.

An RF signal received by the antenna 52 is inputted to the LNA 56 via the band-pass filter 54. The LNA 56 amplifies the RF signal with a low noise and outputs it to the I signal mixer 62 and the Q signal mixer 68, wherein the I signal and the Q signal are quadrature baseband signals. The local oscillator 58 outputs a local (Lo) signal having a local frequency. The phase shifter 60 outputs the local signal to the I signal mixer 62 without shifting its phase, while outputs the local signal to the Q signal mixer 68 with its phase shifted 90 degrees.

The mixers 62 and 68 mix the RF signals and the Lo signals to output signals having a difference frequency between them to the first low-pass filter circuit 64 and the second low-pass filter circuit 70, respectively. Output signals of the first low-pass filter circuit 64 and the second low-pass filter circuit 70 are amplified by the variable gain amplifiers 65 and 71 in each system. Output signals of the variable gain amplifiers 65 and 71 in each system are respectively converted to digital signals by the first AD converter 66 and the second AD converter 72, and are outputted to the baseband portion 80. The signals are hereinafter subjected to digital signal processing by the DSP (Digital Signal Processor) in the baseband portion 80.

The various circuits using the variable impedance circuit 100 illustrated in FIGS. 7-10 are applicable to a circuit element of the communication system 600. For example, the amplifier 500 illustrated in FIG. 10 is applicable to the variable gain amplifiers 65 and 71. In addition, the low-pass filter circuit 200 illustrated in FIG. 7 is applicable to the first low-pass filter circuit 64 and the second low-pass filter circuit 70. The differential amplifier circuit 300 illustrated in FIG. 8 is applicable to the LNA (Low Noise Amplifier) 56 or the mixers 62 and 68. When applying to the mixers 62 and 68, a resonator is used for the loads L1 and L2. The linearity can be improved better than the case where a conventional variable impedance is used, over a wide band by applying various circuits using the variable impedance circuit 100 according to the embodiment.

As mentioned above, the present invention has been described based on some embodiments. These embodiments are intended solely for the purpose of illustration, and it should be understood by those skilled in the art that various modifications are possible in combining those various components and various processing and those modifications also fall in the scope of the present invention.

Although the first transistor M1 and the second transistor M2 are constituted by N channel type MOSFETs in FIG. 2, a P channel type MOSFET may also be used. Although the filter circuit was constituted by an OTA and a capacitance in FIG. 7, an op-amp, a capacitance, and a resistance may also be used. In the inverting amplifier illustrated in FIG. 10, a differentiation circuit or an integration circuit may also be constituted by replacing either one of the variable impedance circuits connected to the op-amp, with a capacitance. Although the variable impedance circuit is applied to a receiver in FIG. 11, the circuit is also applicable to a transmitter.

What is claimed is:

1. A variable impedance circuit in which a first transistor and a second transistor are connected in series, the first transistor comprising:
a first terminal that receives one of differential input signals;
a second terminal that receives a control signal for varying an impedance;
a third terminal connected to the second transistor; and a fourth terminal that supplies a potential to a substrate,
and the second transistor comprising:
a fifth terminal that receives the other of the differential input signals;
a sixth terminal that receives the control signal;
a seventh terminal connected to the first transistor; and
an eighth terminal that supplies a potential to a substrate,
wherein
the third terminal, the fourth terminal, the seventh terminal, and the eighth terminal, are connected together.

2. The variable impedance circuit according to claim 1 further comprising:
a first resistance that is connected to the first terminal and divides one of the differential input signals to supply it to the first transistor; and
a second resistance that is connected to the fifth terminal and divides the other of the differential input signals to supply it to the second transistor.

3. The variable impedance circuit according to claim 1 further comprising:
a parallel resistance that is connected in parallel to the variable impedance circuit and receives the differential input signal.

4. The variable impedance circuit according to claim 2 further comprising:
a parallel resistance that is connected in parallel to the variable impedance circuit and receives the differential input signal.

5. A variable impedance system comprising:
a plurality of the variable impedance circuits according to claim 1,
wherein
each impedance of the plurality of the variable impedance circuits is controlled by a single control signal.

6. A filter circuit in which a plurality of differential filter units are connected in multi-stage cascade, wherein
the filter unit in each stage is provided with each variable impedance circuit of the variable impedance system according to claim 5.

7. The filter circuit according to claim 6,
wherein
the Q factor or the pole of the filter circuit is controlled by the single control signal.

8. An amplifier,
wherein
the variable impedance circuit according to claim 1 is provided between the output terminals of a differential amplifier circuit.

9. An amplifier,
wherein
the variable impedance circuit according to claim 1 is connected to at least one of the input terminal of an operational amplifier or a feedback path of the operational amplifier.

10. A communication system comprising:
a local oscillator that oscillates at a predetermined frequency;
a mixer circuit that mixes an oscillation signal of the local oscillator and a signal received by an antenna; and
the filter circuit according to claim 6 that filters a signal subjected to frequency conversion by the mixer circuit.

11. A communication system comprising:
a local oscillator that oscillates at a predetermined frequency;
a mixer circuit that mixes an oscillation signal of the local oscillator and a signal received by an antenna; and
the amplifier according to claim 8 that amplifies a signal subjected to frequency conversion by the mixer circuit.
